(19) United States
(12) Patent Application Publication
(10) Pub. No.: US 2017/0221911 A1
(43) Pub. Date: Aug. 3, 2017

(54) FLASH MEMORY AND METHOD OF FABRICATING THE SAME

(71) Applicant: UNITED MICROELECTRONICS CORP., Hsin-Chu City (TW)

(72) Inventors: Liang Yi, Singapore (SG); Ko-Chi Chen, Taoyuan City (TW); Shen-De Wang, Hsinchu County (TW)

(21) Appl. No.: 15/081,946

(22) Filed: Mar. 28, 2016

(30) Foreign Application Priority Data
Jan. 29, 2016 (CN) 201610065119.6

(51) Int. Cl. H01L 27/115; G11C 16/14; H01L 21/28; G11C 16/10; H01L 21/3205; H01L 29/66; H01L 29/423; H01L 29/788; G11C 16/04; H01L 21/311

(52) U.S. Cl. CPC H01L 27/11521; G11C 16/0408; G11C 16/14; H01L 21/28273; H01L 21/31111; H01L 21/31144; H01L 21/32055; H01L 29/66825; H01L 29/42328; H01L 29/7883; G11C 16/10

(57) ABSTRACT

The flash memory includes a stacked gate disposed on a substrate. The stacked gate includes an erase gate and two floating gates. Each floating gate has an acute angle pointing toward the erase gate. There is a high electric field formed around the acute angle so that the flash memory can perform an erase mode even at a lower operational voltage. Furthermore, the flash memory does not use any control gate to perform a write mode.

### BACKGROUND OF THE INVENTION

1. Field of the Invention

The present invention relates to a flash memory and a method of fabricating the same, and particularly to a flash memory does not use a control gate during a write mode.

2. Description of the Prior Art

Flash memory is a type of electronic memory media that can hold its data in the absence of operating power. Flash memory can be programmed, erased, and reprogrammed during its useful life. Flash memory is becoming increasingly popular as a reliable, compact, and inexpensive nonvolatile memory in a number of consumer, commercial, and other applications.

As electronic devices get smaller and smaller, it becomes desirable to reduce the size of the flash memory as well. Furthermore, the amount of data that can be stored per unit area on a flash memory unit preferably increases.

Therefore, a different method of fabricating a flash memory is needed to provide a flash memory with efficient data storage, and having a reduced size.

### SUMMARY OF THE INVENTION

It is therefore an object of this invention to provide a method of fabricating a flash memory, comprising providing a substrate covered by a first oxide layer, a first polysilicon layer, a second oxide layer and a patterned mask, wherein the patterned mask comprises two openings, and the second oxide layer is exposed through each of the openings. Then, part of the second oxide layer and part of the first oxide layer are removed by taking the patterned mask as a mask to form two first trenches within the first polysilicon layer, wherein each of the first trenches comprises a sidewall, and the sidewall is not perpendicular to a top surface of the substrate. Later, a third oxide layer is formed to fill in the first trenches and the openings, and a top surface of the third oxide layer is aligned with a top surface of the patterned mask. After that, the entire patterned mask, the second oxide layer directly below the patterned mask and the first polysilicon layer directly below the patterned mask are removed to form a second trench, wherein the remaining first polysilicon layer and the remaining third oxide layer form two stacked structures, and the first polysilicon layer in each stacked structure comprises two acute angles. Next, part of the third oxide layer is removed to widen the second trench and to make the acute angles in each of the stacked structures exposed. Subsequently, a fourth oxide layer is formed to conformally cover the acute angles. Subsequently, a second polysilicon layer is formed to fill in the second trench. Later, a fifth oxide layer is formed to cover the second polysilicon layer and the first polysilicon layer. Then, two third polysilicon layers respectively fill in the third trench in each of the stacked structures. Finally, two fourth trenches are respectively formed to penetrate each of the third polysilicon layers.

It is a further object of this invention to provide a flash memory, which includes a substrate. A stacked gate is disposed on the substrate, wherein the staked gate comprises an erase gate and two floating gates, the floating gates are respectively disposed at two opposite sides of the erase gate, each of the floating gates has a first acute angle extending under the erase gate and the first acute angles overlapping the erase gate. Two select gates are respectively disposed at two sides of the stacked gate. A tunneling oxide is disposed between the stacked gate and the substrate, and between each select gate and the substrate. An inter-gate oxide is disposed between the erase gate and the floating gates, and between the select gates and the erase gate. A first doping region is disposed in the substrate under the erase gate, and part of the first doping region overlaps each of the floating gates.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 13 depict a method of fabricating a flash memory according to a first preferred embodiment of the present invention, Wherein:

FIG. 2A depicts a sidewall of the first trench according to the first preferred embodiment; and

FIG. 2B depicts a sidewall of the first trench according to a second preferred embodiment.

FIG. 14 depicts a flash memory fabricated by the method disclosed in the first preferred embodiment.

### DETAILED DESCRIPTION

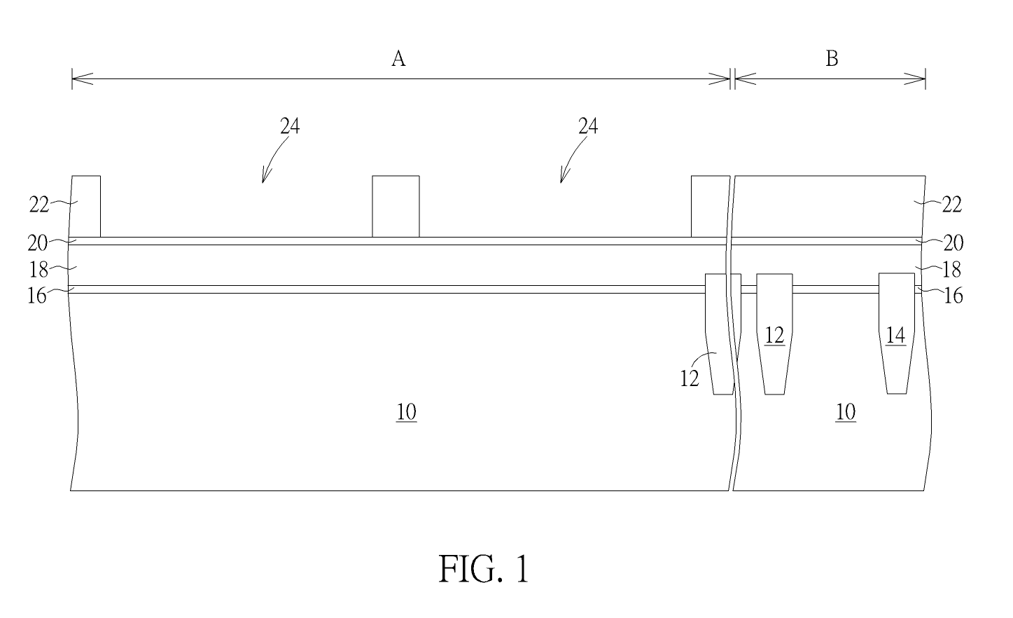

FIG. 1 to FIG. 13 depict a method of fabricating a flash memory according to a first preferred embodiment of the present invention. As shown in FIG. 1, a substrate 10 is provided. The substrate 10 is divided into a memory region A and a logic transistor region B. A shallow trench isolation (STI) 12 may be optionally disposed within the memory region A on the substrate 10. Another STI 14 may be optionally disposed within the logic transistor region B on the substrate 10. The substrate 10 including the memory region A and the logic transistor region B is sequentially covered by a first oxide layer 16, a first polysilicon layer 18, a second oxide layer 20 and a patterned mask 22. The first oxide layer 16 and the second oxide layer 20 are preferably silicon oxide. The first polysilicon layer 18 is preferably polysilicon. In addition, the patterned mask 22 within the memory region A includes two openings 24, and the second oxide layer 20 is exposed through each of the openings 24. Furthermore, the STI 12 and the STI 14 penetrate the first silicon oxide layer 16, and enter the first polysilicon layer 18.

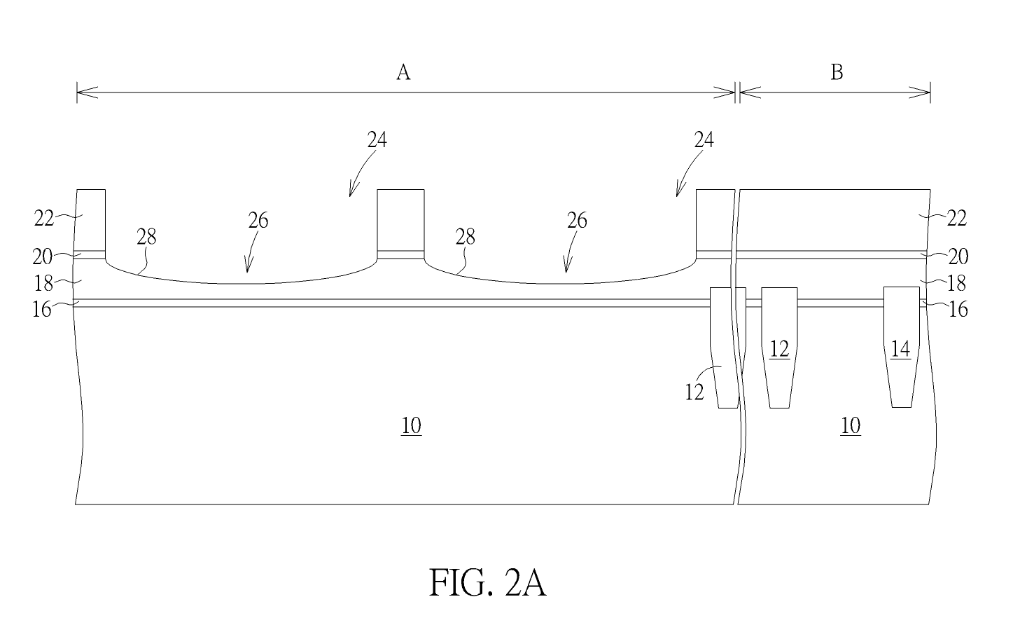

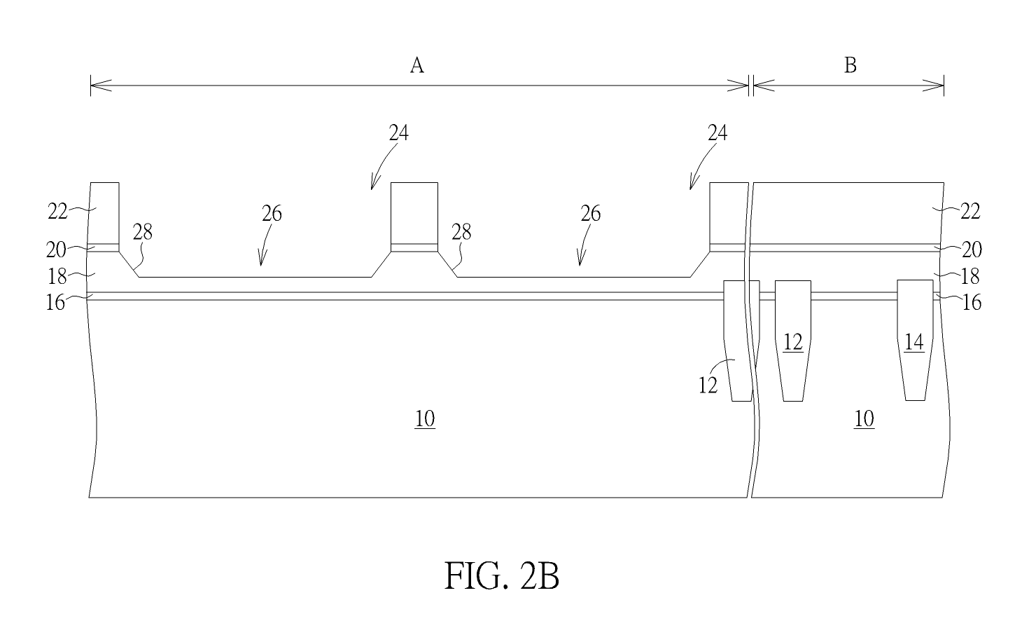

As shown in FIG. 2A, part of the second oxide layer 20 and part of the first polysilicon layer 18 are removed to form two first trenches 26 in the first polysilicon layer 18 by taking the patterned mask 22 as a mask. Each of the first trenches 26 includes a sidewall 28. Each sidewall 28 is not perpendicular to a top surface of the substrate 10. Moreover, the sidewall 28 of each first trench 28 may be curved. Alternately, as shown in FIG. 2B, the sidewall 28 of each first trench 28 may be a slope, but not limited to it. Other profiles can be applied to the sidewall 28, as long as the sidewall 28 is not perpendicular to a top surface of the substrate 10. The profile of the sidewall 28 takes the curved profile shown in FIG. 2A as an example in the following description. Furthermore, the second oxide layer 20 and the first polysilicon layer 18 may be preferably removed by a dry etching process. Other removing processes such as a wet etching process can also be used based on different requirements. Furthermore, the pattern mask 22 is preferably silicon nitride.

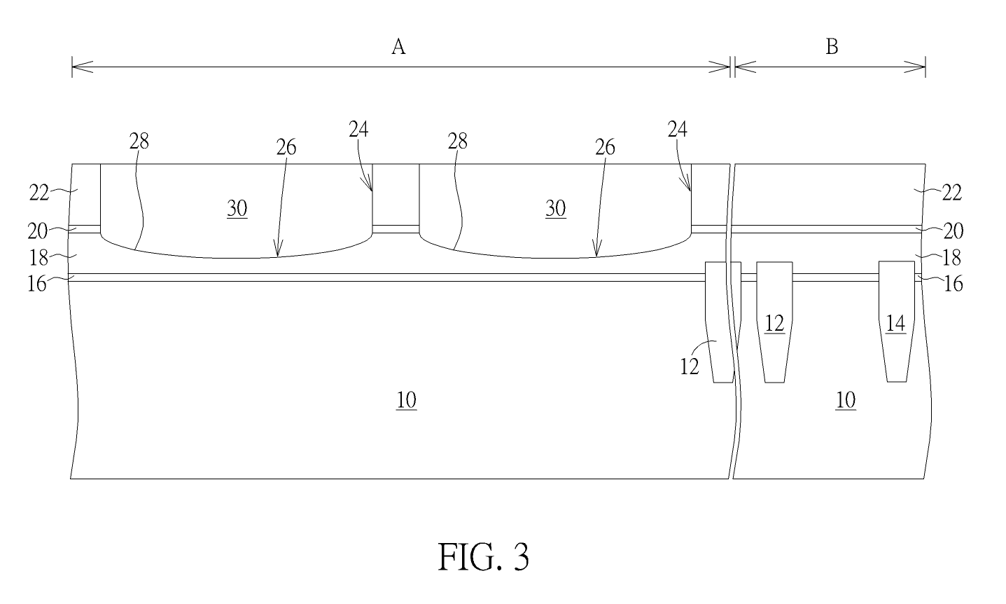

As shown in FIG. 3, a third oxide layer 30 is formed to fill up each of the first trenches 26 and openings 24, and a top surface of the third oxide layer 30 is aligned with a top surface of the patterned mask 22. In detail, the steps of forming the third oxide layer 30 include forming the third oxide layer 30 to fill up each of the first trenches 26 and openings 24, and cover the patterned mask 22. Then, a chemical mechanical polishing process is used to remove the third oxide layer 30 which is higher than the top surface of the patterned mask 22. The third oxide layer 30 is preferably silicon oxide.

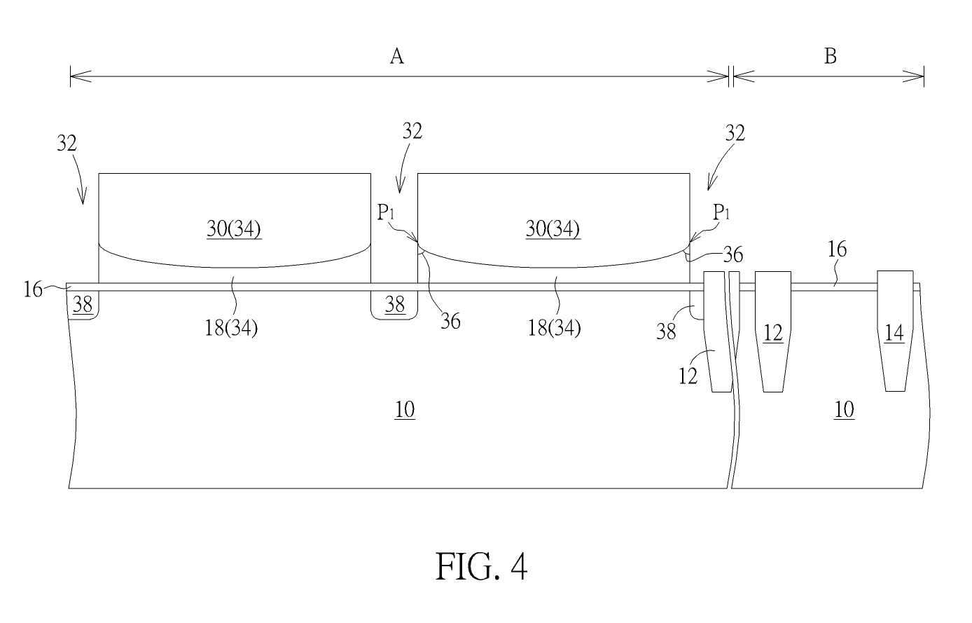

As shown in FIG. 4, the patterned mask 22, the second oxide layer 20 directly below the patterned mask 22 and the first polysilicon layer 18 directly below the patterned mask 22 are entirely removed to form at least one second trench 32 within the memory region A. The remaining first polysilicon layer 18 and the remaining third oxide layer 30 form two stacked structures 34. In other words, each stack structure 34 includes part of the first polysilicon layer 18 and part of the third oxide 30. Moreover, a top surface of the first polysilicon layer 18 in each of the stacked structures 34 has a concave profile. The first polysilicon layer 18 includes two acute angles 36. Each of the acute angles 36 of the first polysilicon 18 in each stacked structure 34 has a tip P₁, and the tip P₁ points away from the stacked structure 34. Furthermore, the patterned mask 22, the second oxide layer 20 and the first polysilicon layer 18 within the logic transistor region B are entirely removed. The removing step of the patterned mask 22, the second oxide layer 20 and the first polysilicon layer 18 in FIG. 4 can utilize a dry etching process. Moreover, the number of the second trench 32 can be adjusted based on the total number of the flash memory. FIG. 4 takes one full second trench 32, and two partial second trenches 32 as an example. Next, a photoresist (not shown) is formed to cover the logic transistor region B, and exposes the memory region A. Then, an implantation process is performed to form a first doping region 38 in the substrate 10 by taking the stacked structures 34 as a mask. In other words, the first doping region 38 is in the substrate 10 which is directly below the second trench 32. Later, the photoresist is removed.

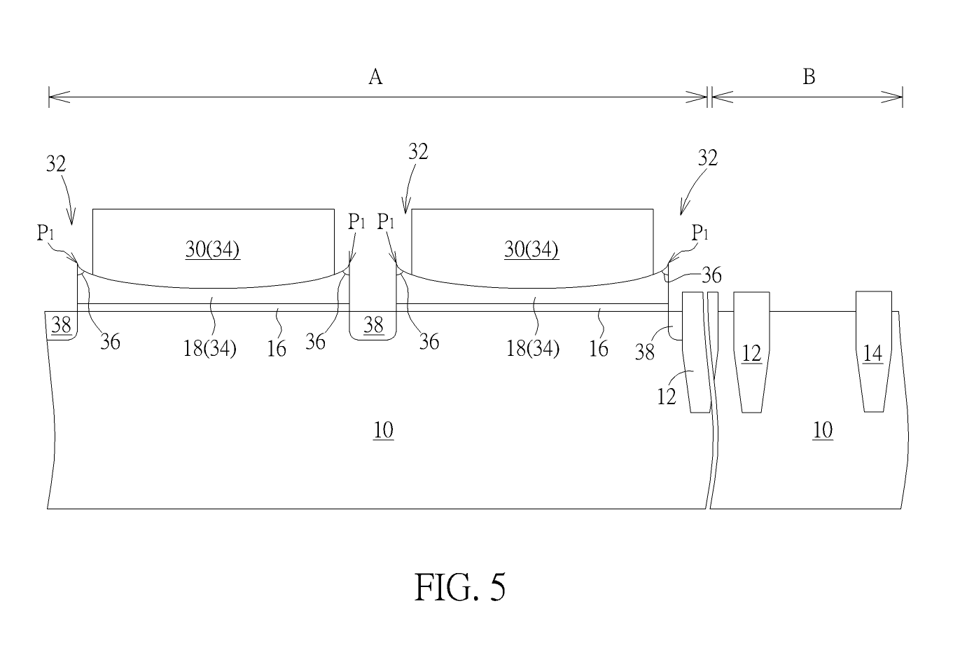

As shown in FIG. 5, part of the third oxide layer 30 in each of the stacked structures 34 is removed to widen the second trench 32 and exposes the tip P₁ of the acute angle 36 in each stacked structure 34. Moreover, the first oxide layer 16 within the memory region A and not covered by the first polysilicon layer 18, and the entire first oxide layer 16 within the logic transistor region B are removed to expose the substrate 10 while removing the part of the third oxide layer 30 in the stacked structures 34. The third oxide layer 30 and the first oxide layer 16 are preferably removed by a wet etching process.

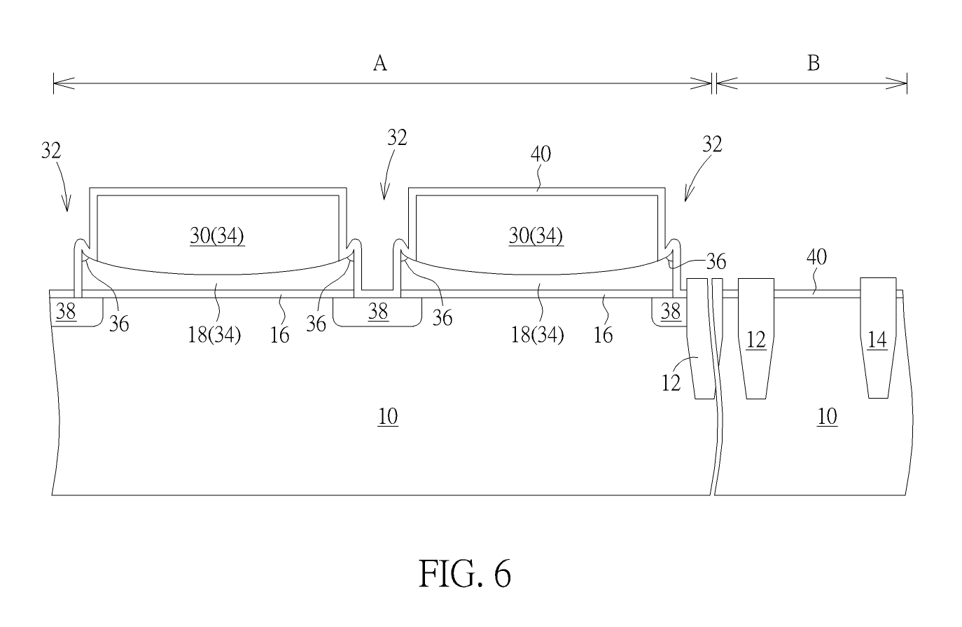

As shown in FIG. 6, a fourth oxide layer 40 is formed to conformally cover the acute angles 36 of the first polysilicon layer 18, the third oxide layer 30 and the exposed substrate 10. Now, the first polysilicon layer 18 is encapsulated by the third oxide layer 30, the fourth oxide layer 40 and the first oxide layer 16. The fourth oxide layer 40 is preferably silicon oxide. Next, a rapid thermal anneal process is performed to densify the fourth oxide layer 40. During the thermal anneal process, the first doping region 38 in the substrate 10 diffuses because of the rapid thermal anneal process, and the diffused first doping region 38 partly overlaps the first polysilicon layer 18.

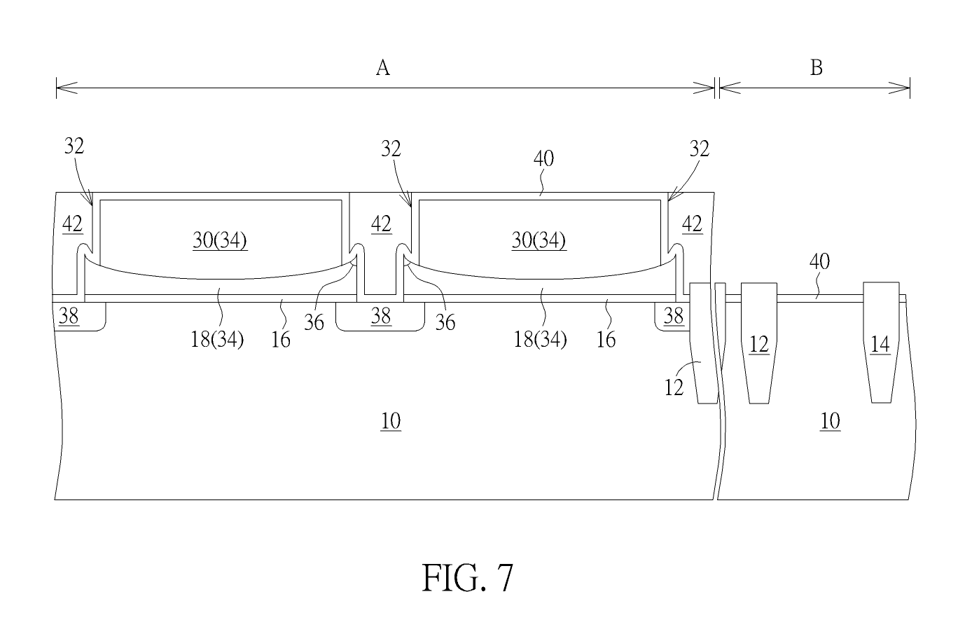

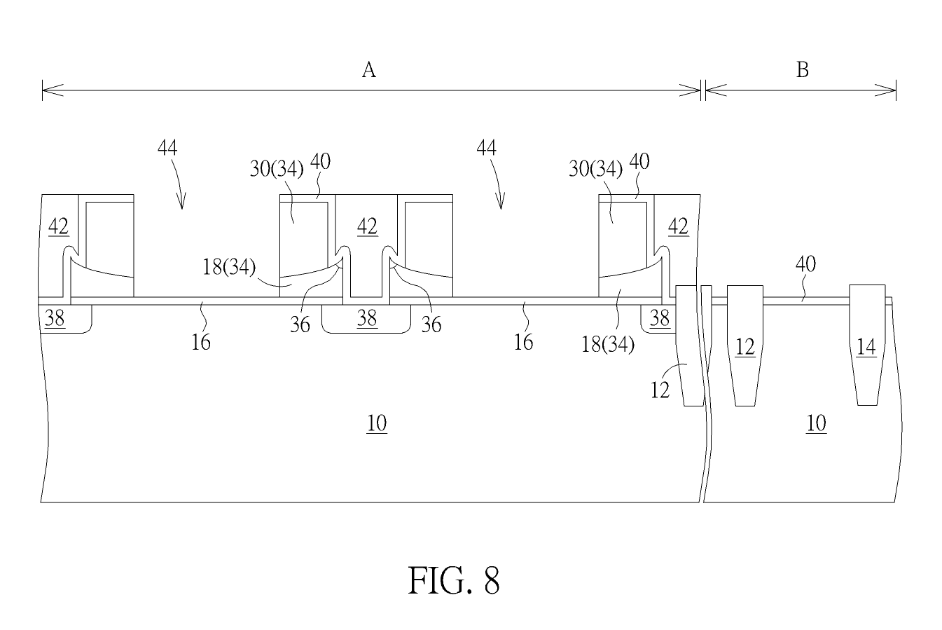

As shown in FIG. 7, a second polysilicon layer 42 is formed to fill in the second trench 32 within the memory region A. A top surface of the second polysilicon layer 42 is aligned with the fourth oxide layer 40. As shown in FIG. 8, a third trench 44 is formed in each of the stacked structures 34. The third trench 44 penetrates the third oxide layer 30 and the first oxide layer 18, and exposes the first oxide layer 16 from the bottom of the third trench 44. Moreover, the first polysilicon layer 18 is exposed from the sidewall of the third trench 44.

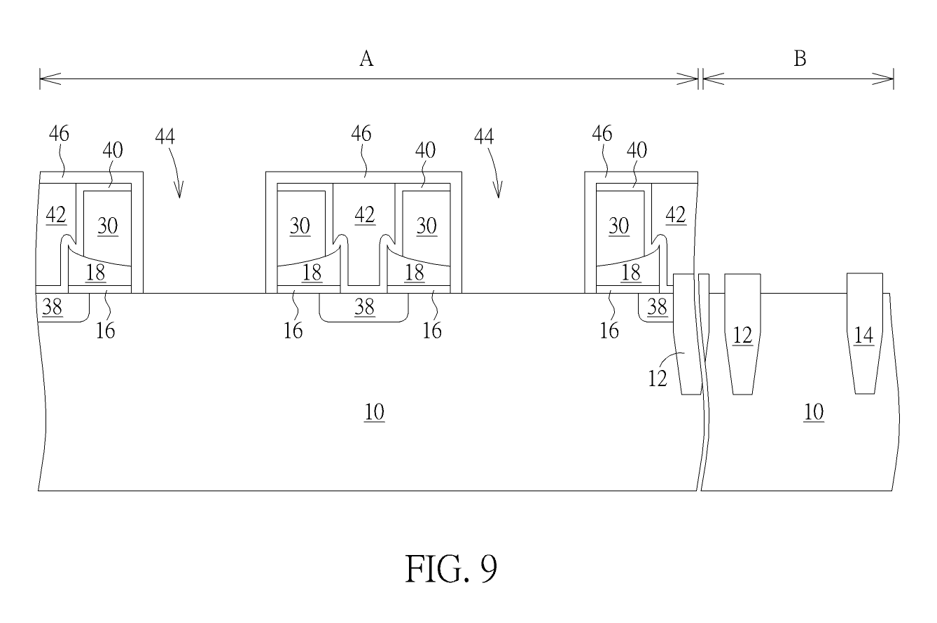

As shown in FIG. 9, an oxidation process is performed to oxidize the first polysilicon layer 18 and the second polysilicon layer 42 to form a fifth oxide layer 46 on the surface of the first polysilicon layer 18 and the second polysilicon layer 42. The fifth oxide layer 46 is preferably silicon oxide. Next, the first oxide layer 16 exposed from the bottom of the third trench 44, and the first oxide layer 16 within the logic transistor region B are removed.

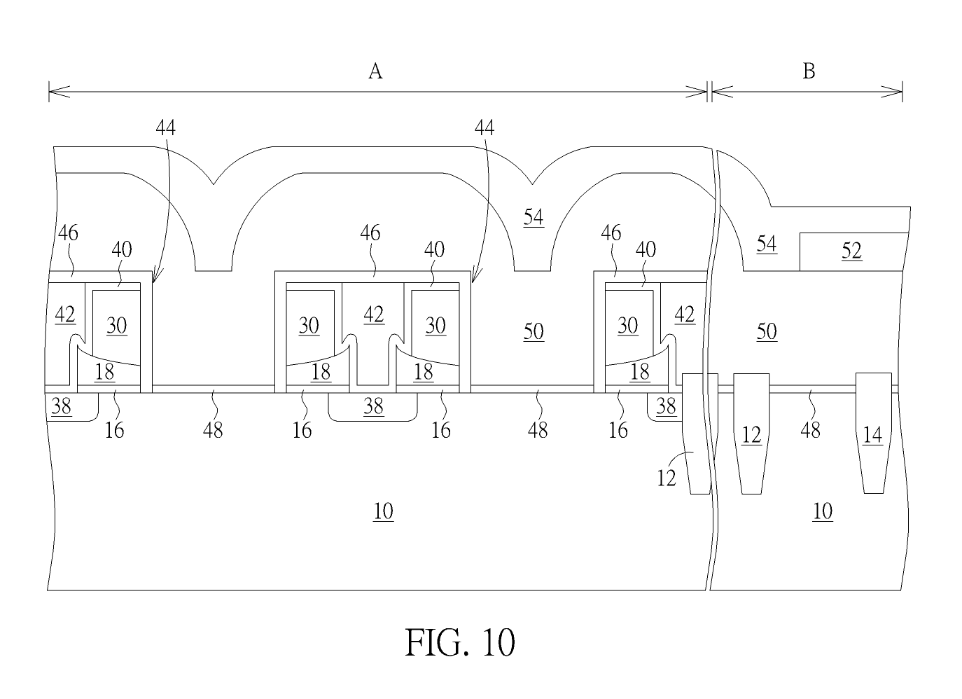

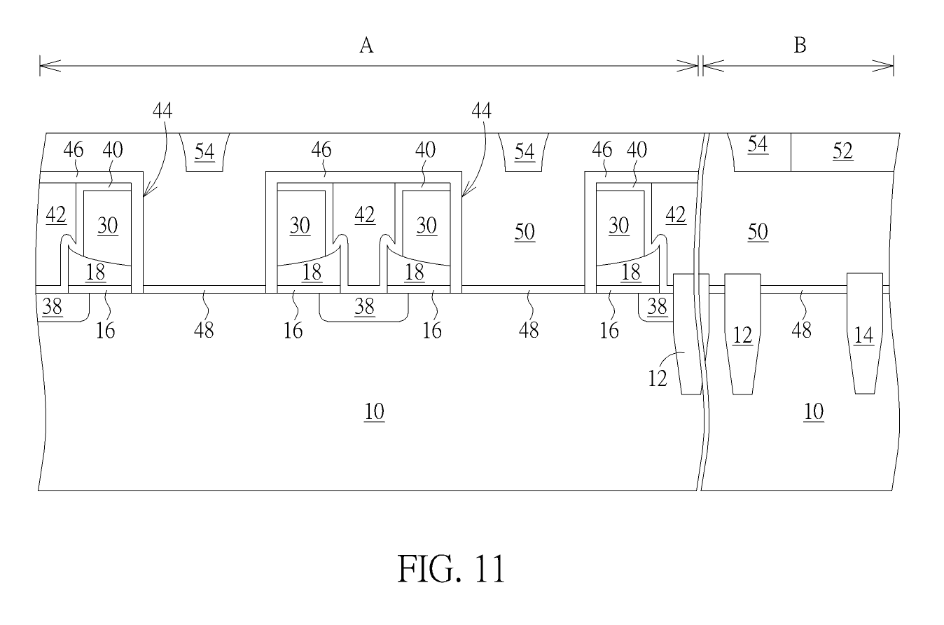

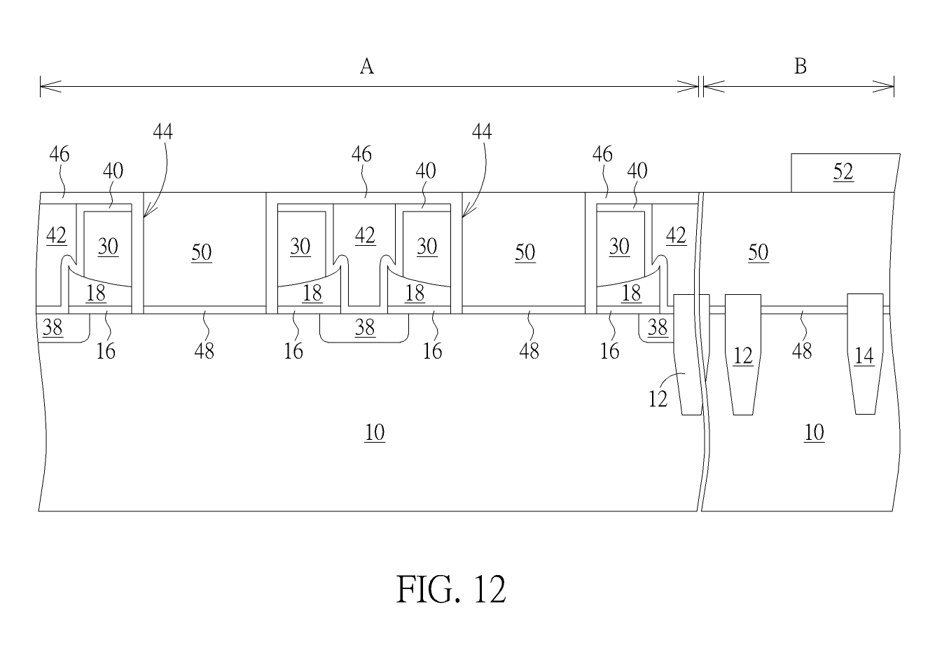

As shown in FIG. 10, a sixth oxide layer 48 is formed to cover the bottom of each of the third trench 44, and the substrate 10 within the logic transistor region B. The sixth oxide layer 48 is preferably formed by an oxidation process. Next, a third polysilicon layer 50 is blankly formed to cover the memory region A and fills in each of the third trenches 44. The third polysilicon layer 50 covers the sixth oxide layer 48 within the logic transistor region B. After that, a mask layer 52 is formed to cover the third polysilicon layer 50 within the logic transistor region B. Later, a sacrifice layer 54 such as a polysilicon layer is formed to conformally cover the third polysilicon layer 50 and the mask layer 52. As shown in FIG. 11, the sacrifice layer 54 and part of the third polysilicon layer 50 are removed by a chemical mechanical polishing process and takes the mask layer 52 as an etching stop layer. After the chemical mechanical polishing process, a top surface of the remaining third polysilicon layer 50 is aligned with a top surface of the mask layer 52. As shown in FIG. 12, the third polysilicon layer is etched back and dissected into three disconnected third polysilicon layers 50. Two of the third polysilicon layers 50 are disposed within the memory region A, and one of the third polysilicon layers 50 is disposed within the logic transistor region B. A top surface of each of the third polysilicon layers 50 is aligned with a top surface of the fifth oxide layer 46.

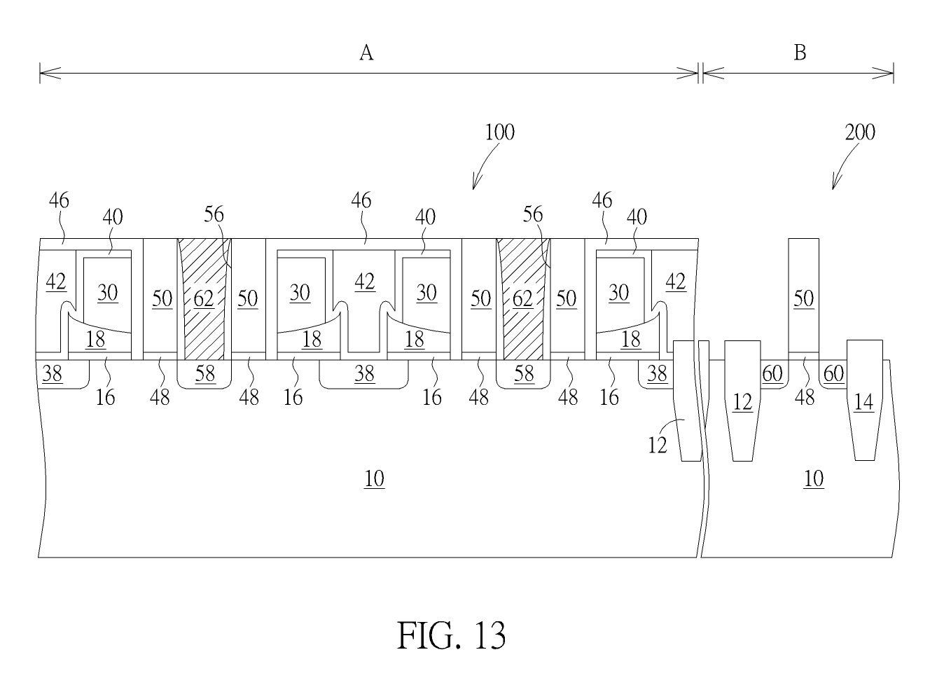

As shown in FIG. 13, the mask layer 52 is removed. Then, a fourth trench 56 is formed in each of the third polysilicon layers 50 within the memory region A. The fourth trench 56 penetrates the third polysilicon layer 50 and the sixth oxide layer 48 so as to expose the substrate 10. During the formation of the fourth trench 56, the third polysilicon layer 50 and the sixth oxide layer 48 within the logic transistor region B are simultaneously patterned into a gate electrode and a gate dielectric respectively. Later, an ion implantation process is performed to form a second doping region 58 in the substrate 10 which is directly below each of the fourth trenches 56, and to form a source/drain doping region 60 at two sides of the gate electrode formed by the third polysilicon layer 50. Now, the gate electrode formed by the third polysilicon layer 50, the gate dielectric layer formed by the sixth oxide layer 48, and the source/drain doping region 60 comprise a logic transistor 200. The first polysilicon layer 18 between two fourth trenches 56, the second polysilicon layer 42, the third polysilicon layer 50, the third oxide layer 30, the fourth oxide layer 40, the fifth oxide layer 46, the sixth oxide layer 48, the first doping region 38, and the second doping region 58 form a flash memory 100 of the present invention. Furthermore, after forming the flash memory 100, a conductive layer can fill in the fourth trench 56 to serve as a bit line 62.

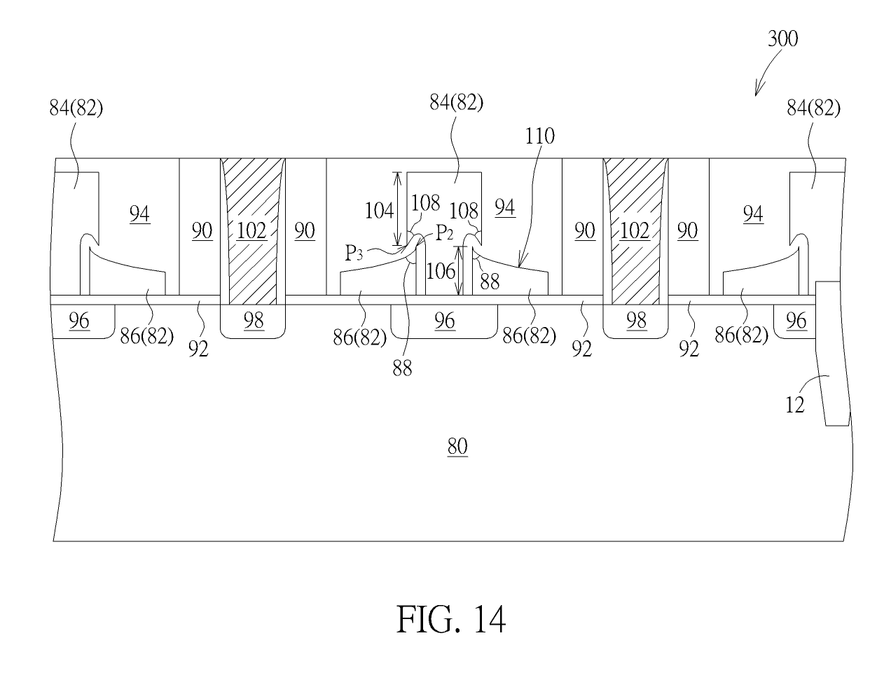

FIG. 14 depicts a flash memory fabricated by the method disclosed in the first preferred embodiment. As shown in FIG. 14, a flash memory 300 includes a substrate 80. A stacked gate 82 is disposed on the substrate 80. The staked gate 82 includes an erase gate 84 and two floating gates 86, the floating gates 86 is respectively disposed at two opposite sides of the erase gate 84. Each of the floating gates 86 has an acute angle 88 extending under the erase gate 84 and the acute angles 88 partly overlap the erase gate 84. Two select gates 90 are respectively disposed at two sides of the stacked gate 82. A tunneling oxide 92 is disposed between the stacked gate 82 and the substrate 80, and between each select gate 90 and the substrate 80. An inter-gate oxide 94 is disposed between the erase gate 84 and the floating gates 86, and between the select gates 90 and the erase gate 84. A first doping region 96 is disposed in the substrate 80 under the erase gate 84. Part of the first doping region 96 overlaps each of the floating gates 86. Two second doping regions 98 are respectively disposed in the substrate 80 at one side of each of the select gates 90. A bit line 102 is disposed at one side of the each of the select gates 90. The bit line 102 contacts the second doping regions 98. The select gates 90, the erase gate 84, and the floating gates 86 are preferably polysilicon. The tunneling oxide 92 and the inter-gate oxide 94 are preferably silicon oxide.

Furthermore, the erase gate includes a first portion 104 and a second portion 106. A width of the first portion 104 is greater than a width of the second portion 106. The acute angles 88 are disposed below the first portion 104. Each acute angle 88 has a tip P₂. The tip P₂ points to the erase gate 84. Moreover, the erase gate 84 has two acute angles 108. Each of the acute angles 108 corresponds to one of the acute angles 88. In detail, each of the acute angles 108 has a tip P₃. The tip P₃ of each of acute angles 108 points to different floating gates 86. Furthermore, a bottom of the erase gate 84 contacts the tunnel oxide 92. A bottom of each of the floating gates 86 also contacts the tunnel oxide 92. The bottom of the erase gate 84 is aligned with the bottom of each of the floating gates 86. A top surface of each floating gate 86 is curved, and a height of the top surface of each floating gate 86 declines in a direction away from the erase gate 84. Moreover, a top surface of each floating gates 86 can be a slope. A height of the slope declines in a direction away from the erase gate 84. Please refer to the slope of the sidewall 28 in FIG. 2B for profile of the slope of the floating gate 86.

It is noteworthy that when a write mode of the flash memory 300 is performed, charges flow out from the first doping region 96, and penetrate the tunnel oxide 92 to enter at least one of the floating gates 86. At least one of the select gates 90 controls which floating gates 86 the charges enter, or both of floating gates 86 the charges enter. In other words, the flowing direction of the charges in write mode of the flash memory 300 is not controlled by any control gate. Therefore, there is no control gate disposed in the flash memory 300 of the present invention. In addition, when an erase mode of the flash memory 300 is performed, charges flow out from at least one floating gates 86, penetrate the inter-gate oxide 94 and enter the erase gate 84. Because the tips P₂ of the floating gates 86 form a high electric field, the erase mode can be performed at lower operational voltage by using the Fowler-Nordheim tunneling effect to make the charges enter the erase gate 84.

Table 1 below illustrates operational voltages of the select gates 90, the bit line 102, the erase gate 94 and the first doping region 96 of flash memory 300 in a read mode, an erase mode, and a write mode. For example, when the write mode is performed, the operational voltage of the select gate 90 is 0.8-1 V. The operational voltage of the bit line 102 is 0.45 V. The operational voltage of the erase gate 84 is 5 V. The operational voltages of the first doping region 96 is 6.5 V. The operational voltages of the select gates 90, the bit line 102, the erase gate 94 and the first doping region 96 can be adjusted based on different requirements, and the values of the operational voltages are not limited to that in table 1.

TABLE 1

| | | | | Operational |
|---|---|---|---|---|
| | | | | voltage of |
| | Operational | Operational | Operational | first |
| | voltage of | voltage of | voltage of | doping |
| | select gate | bit line | erase gate | region |
| Read | 1.1-2.5 V | 0.8 V | 1.1-2.5 V | 0 V |
| mode | | | | |
| Erase | 0 V | 0 V | 11.5 V | 0 V |
| mode | | | | |
| Write | 0.8-1 V | 0.45 V | 5 V | 6.5 V |
| mode | | | | |

The fabricating method of the flash memory combines the fabricating steps of the logic transistor and the flash memory. The write mode of the flash memory of the present invention is performed by using the first doping region directly below the erase gate and the floating gates, so a control gate is not needed in the write mode. Therefore, there is no control gate in the flash memory of the present invention, and the space originally occupied by the control gate can be saved. As a result, the size of the flash memory is reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of fabricating a flash memory, comprising:
providing a substrate covered by a first oxide layer, a first polysilicon layer, a second oxide layer and a patterned mask, wherein the patterned mask comprises two openings, and the second oxide layer is exposed through the openings;
removing part of the second oxide layer and part of the first oxide layer by taking the patterned mask as a mask to form two first trenches within the first polysilicon layer, wherein each of the first trenches comprises a sidewall, and the sidewall is not perpendicular to a top surface of the substrate;
forming a third oxide layer filling in the first trenches and the openings, and a top surface of the third oxide layer aligned with a top surface of the patterned mask;
removing the entire patterned mask, the second oxide layer directly below the patterned mask and the first polysilicon layer directly below the patterned mask to form a second trench, wherein the remaining first polysilicon layer and the remaining third oxide layer form two stacked structures, and the first polysilicon layer in each stacked structure comprises two acute angles;
removing part of the third oxide layer to widen the second trench and to make the acute angles in each of the stacked structures exposed;
forming a fourth oxide layer conformally covering the acute angles;
forming a second polysilicon layer filling in the second trench;
forming a third trench in each of the stacked structures and the third trench penetrating the third oxide layer and the first polysilicon layer;
forming a fifth oxide layer covering the second polysilicon layer and the first polysilicon layer;
forming two third polysilicon layers respectively filling in the third trench in each of the stacked structures; and
forming two fourth trenches respectively penetrating each of the third polysilicon layers.

2. The method of fabricating a flash memory of claim 1, further comprising after forming the second trench, forming a first doping region in the substrate directly below the second trench.

3. The method of fabricating a flash memory of claim 1, wherein a top surface of the first polysilicon layer in each of the stacked structures has a concave profile.

4. The method of fabricating a flash memory of claim 3, wherein each of the acute angles of the first polysilicon in each stacked structure has a tip, and the tip points away from the stacked structure.

5. The method of fabricating a flash memory of claim 1, further comprising removing the first oxide layer not covered by the first polysilicon layer while removing part of the third oxide layer to widen the second trench.

6. The method of fabricating a flash memory of claim 5, further comprising when forming the fourth oxide layer conformally covering the acute angles, the fourth oxide layer simultaneously formed on the substrate not covered by the first polysilicon layer.

7. The method of fabricating a flash memory of claim 5, wherein the steps of forming the fifth oxide layer comprises oxidizing a surface of the first polysilicon layer and a surface of the second polysilicon layer.

8. The method of fabricating a flash memory of claim 1, further comprising after forming the third trench, removing the first oxide layer exposed through the third trench to make part of the substrate expose through the third trench.

9. The method of fabricating a flash memory of claim 8, further comprising forming a sixth oxide layer on the substrate exposed through the third trench.

10. The method of fabricating a flash memory of claim 1, further comprising after forming the fourth trenches, forming a second doping region in the substrate directly below each of the fourth trenches.

11. A flash memory, comprising
a substrate;
a stacked gate disposed on the substrate, wherein the staked gate comprises an erase gate and two floating gates, the floating gates are respectively disposed at two opposite sides of the erase gate, each of the floating gates has a first acute angle extending under the erase gate and the first acute angle overlaps the erase gate;
two select gates respectively disposed at two sides of the stacked gate;
a tunneling oxide disposed between the stacked gate and the substrate, and between each select gate and the substrate;
an inter-gate oxide disposed between the erase gate and the floating gates, and between the select gates and the erase gate; and
a first doping region disposed in the substrate under the erase gate, and part of the first doping region overlapping each of the floating gates.

12. The flash memory of claim 11, wherein when a write mode is performed, charges flow out from the first doping region, penetrate the tunnel oxide to enter at least one of the floating gates.

13. The flash memory of claim 11, wherein when an erase mode is performed, charges flow out from at least one floating gates, penetrate the inter-gate oxide and enter the erase gate.

14. The flash memory of claim 11, further comprising two second doping regions respectively disposed in the substrate at one side of each of the select gates.

15. The flash memory of claim 11, wherein the erase gate comprises a first portion and a second portion, a width of the first portion is greater than a width of the second portion, and the first acute angle is disposed below the first portion.

16. The flash memory of claim 11, wherein a bottom of the erase gate contacts the tunnel oxide, a bottom of each of the floating gates contacts the tunnel oxide, and the bottom of the erase gate is aligned with the bottom of each of the floating gates.

17. The flash memory of claim 11, wherein a top surface of each floating gate is curved, and a height of the top surface declines in a direction away from the erase gate.

18. The flash memory of claim 11, wherein a top surface of each floating gate is a slope, a height of the top surface declines in a direction away from the erase gate.

19. The flash memory of claim 11, wherein the erase gate comprises two second acute angles, and the first acute angle of each of the floating gates corresponds to one of the second acute angles.
